(19) United States
(12) Patent Application Publication
(10) Pub. No.: US 2011/0117691 A1
(43) Pub. Date: May 19, 2011

(54) MIXED TRIMMING METHOD

(75) Inventors: Marcel Broekaart, Theys (FR); Marion Migette, Grenoble (FR); Sébastien Molinari, Sassenage (FR); Eric Neyret, Sassenage (FR)

(73) Assignee: S.O.I.TEC SILICON ON INSULATOR TECHNOLOGIES

(21) Appl. No.: 12/933,966

(22) PCT Filed: Jul. 31, 2009
(86) PCT No.: PCT/EP2009/059960

§ 371 Date: Dec. 8, 2010

(30) Foreign Application Priority Data
Sep. 2, 2008 (FR) 0855872

(51) Int. Cl. H01L 21/306; H01L 31/18

(52) U.S. Cl. 438/73; 438/459; 257/E21.23

(57) ABSTRACT

The invention relates to a method of trimming a structure that includes a first wafer bonded to a second wafer, with the first wafer having a chamfered edge. The method includes a first step of trimming the edge of the first wafer by mechanical machining over a predetermined depth in the first wafer. This first trimming step is followed by a second step of non-mechanical trimming over at least the remaining thickness of the first wafer.

### FIELD OF THE INVENTION AND PRIOR ART

The present invention relates to the field of producing multilayer semiconductor structures or substrates (also termed multilayer semiconductor wafers) produced by transfer of at least one layer onto a support. The transferred layer is formed by molecular bonding of a first wafer onto a second wafer or support, the first wafer generally being thinned following bonding. The first wafer may also include all or part of a component or a plurality of microcomponents, as happens with three-dimensional (3D) integration of components, which requires transfer of one or more layers of microcomponents onto a final support, and also as happens with circuit transfer as, for example, in the fabrication of back lit imaging devices.

The edges of the wafers used to form the transferred layers and the supports generally have chamfers or edge roundings serving to facilitate their manipulation and to avoid breakages at the edges that could occur if those edges were to project, such breakages being sources of particles that contaminate the wafer surfaces. The chamfers may be rounded and/or bevelled in shape.

However, the presence of such chamfers prevents good contact between the support and the wafer at their peripheries. As a result, a peripheral zone exists on which the transferred layer is not bonded or not properly bonded to the support substrate. This peripheral zone of the transferred layer must be eliminated since it is liable to break in an uncontrolled manner and contaminate the structure with unwanted fragments or particles.

Thus, once the wafer has been bonded to the support and after any necessary thinning thereof, the transferred layer is then trimmed in order to remove the peripheral zone over which the chamfers extend. Trimming is usually carried out essentially by mechanical machining, in particular by abrasion or grinding from the exposed surface of the transferred layer up to the support.

However, such trimming causes problems with peel-off, both at the bonding interface between the transferred layer and the support and in the transferred layer itself. More precisely, at the bonding interface, peel-off problems correspond to delamination of the transferred layer over certain zones in the vicinity of the periphery of the layer, which delamination may be qualified as macro peel-off. The bonding energy is lower near the periphery of the layer because of the presence of the chamfers. As a consequence, grinding in this region may cause partial detachment of the layer at its bonding interface with the support substrate. Said detachment is more probable when the transferred layer includes components. High temperature anneals, normally carried out after bonding to reinforce the bonding interface, are not used when components are present in the transferred layer since components cannot withstand the temperatures of such anneals.

Further, when the layer comprises components such as circuits, contacts, and in particular zones formed from metal, grinding may cause delamination at the motifs of the components present in the transferred layer, which delamination may be qualified as micro peel-off.

Such phenomena of macro and micro peel-off occur beyond a certain level of heating and/or mechanical stress in the structure during the trimming step. This level is frequently attained during complete trimming of the transferred layer.

### SUMMARY OF THE INVENTION

The aim of the invention is to overcome the disadvantages mentioned above by proposing a method of trimming a structure comprising a first wafer bonded to a second wafer, the first wafer having a chamfered edge and comprising components, said method comprising a first step of trimming the edge of the first wafer carried out by mechanical machining over a predetermined depth in the first wafer followed by a second step of trimming that is at least partially non-mechanical over at least the remaining thickness of the first wafer, said first trimming step being carried out with a grinder including grooves on its lower surface.

Thus, by limiting the depth of mechanical trimming and completing it by trimming that is at least partially non-mechanical, i.e. not solely involving mechanical friction on the wafer, heating and/or stresses responsible for macro and micro peel-off phenomena are limited. Further, by using a grinder including grooves on its lower surface during the first trimming step, evacuation of the material that is removed and circulation of the cooling fluid are improved. This further reduces heating and/or stresses during the first trimming step.

In accordance with one aspect of the invention, during the first trimming step, the first wafer is machined over a depth that is not more than 50% of the thickness of the first wafer. The first trimming step is carried out solely by mechanically wearing away the material of the first wafer, such as by grinding.

In accordance with another aspect of the invention, the first and second trimming steps are carried out over a width that is at least equal to the width over which the chamfered edge extends. The first and second trimming steps may be carried out over a width in the range 2 mm to 8 mm, preferably in the range 2 mm to 5 mm.

In accordance with one implementation of the method, the second trimming step is carried out by chemical etching.

In accordance with another implementation, the second trimming step is carried out by chemical plasma etching.

In accordance with yet another implementation, the second trimming step is carried out by chemical-mechanical polishing (CMP).

In accordance with still yet another implementation, the second trimming step is carried out by fracture or breakage of the remaining portion to be trimmed after the first trimming step.

The present invention also provides a method of producing a three-dimensional composite structure comprising at least one step of producing a layer of components on one face of a first wafer, a step of bonding the face of the first wafer comprising the layer of components onto a second wafer, and a step of trimming at least the first wafer carried out in accordance with the trimming method of the invention.

The use of the trimming method of the invention means that three-dimensional structures can be produced by stacking two or more wafers, minimizing the risks of delamination both at the bonding interfaces between the wafers and at the component layers. One of the component layers may include image sensors.

### BRIEF DESCRIPTION OF THE FIGURES

FIGS. 1A to 1E are diagrammatic views of a trimming method in accordance with an implementation of the invention;

FIG. 2 is a flow diagram of the steps carried out during the method illustrated in FIGS. 1A to 1E;

FIGS. 3A to 3F are diagrammatic views showing the production of a three-dimensional structure employing the trimming method of the present invention;

FIG. 4 is a flow diagram of the steps carried out during production of the three-dimensional structure illustrated in FIGS. 3A to 3F;

FIG. 5 is a view showing the lower surface of the grinder used in FIG. 3D.

### DETAILED DESCRIPTION OF IMPLEMENTATIONS OF THE INVENTION

The present invention is of general application to trimming a structure comprising at least two wafers assembled together by molecular bonding or any other type of bonding such as anodic bonding, metallic bonding, or bonding with adhesive, it being possible for components to be formed beforehand in the first wafer that is then bonded to the second wafer that constitutes a support. The wafers are generally of circular outline, possibly with different diameters, in particular diameters of 100 millimeters (mm), 200 mm, or 300 mm. The term “components” as used here means any type of element produced with materials that differ from the material of the wafer and that are sensitive to the high temperatures normally used to reinforce the bonding interface. These components correspond in particular to elements forming all or a portion of an electronic component or a plurality of electronic microcomponents, such as circuits or contacts or active layers that may be damaged or even destroyed if they are exposed to high temperatures. The components may also correspond to elements, motifs, or layers that are produced with materials with expansion coefficients different from that of the wafer and that, at high temperature, are liable to create different degrees of expansion in the wafer, which may deform and/or damage it.

In other words, when the first wafer includes such components, it cannot undergo high temperature anneals after bonding. As a consequence, the bonding energy between the wafers is limited, typically to a value in the range 500 mJ/m² [millijoules/square meter] to 1 J/m² [joule/square meter], which renders the resulting structure rather more sensitive to the phenomenon of macro peel-off during mechanical trimming, as described above. Further, as explained above, the trimming may also cause micro peel-off, corresponding to delamination in the first wafer at the components (detachment in one or more of the stacks forming the components in the first wafer).

More generally, the invention is of particular application to assembled structures that cannot be subjected to a high temperature bonding anneal, as also happens with heterostructures formed by an assembly of wafers with different expansion coefficients (for example silicon-on-sapphire, silicon-on-glass, etc). It may also apply to more standard silicon-on-insulator (SOI) type structures, namely SOI structures in which the two wafers are composed of silicon. For this type of structure, the invention is of particular application to the formation of structures with a layer that presents thickness of more than 10 micrometers (μm), or that comprises a stack of layers with different natures. In fact, it has been observed that these structures are liable to be damaged during the trimming step when said trimming is carried out using the known prior art technique.

To this end, the present invention proposes carrying out trimming in two steps, namely a first step of trimming action or machining that is entirely mechanical (grinding, abrasion, shaving, etc) but that is limited to a predetermined depth in the first wafer, followed by a second trimming step carried out with means that are non-mechanical at least in part, i.e. means not solely involving friction or mechanical wear on the wafer. Thus, the heating and/or stresses that are responsible for the phenomena of macro and micro peel-off are limited.

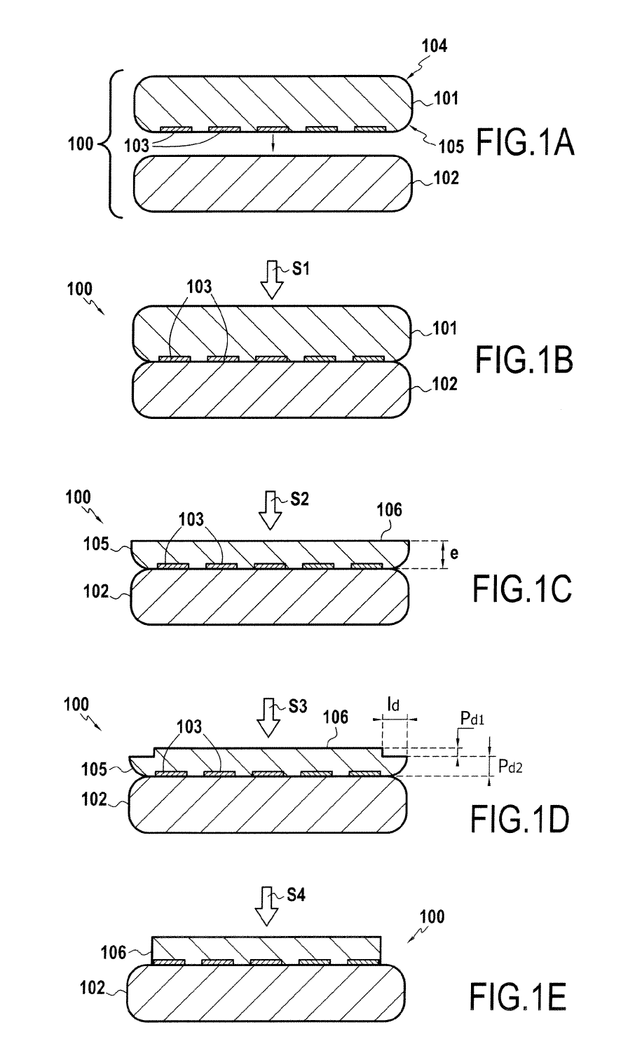

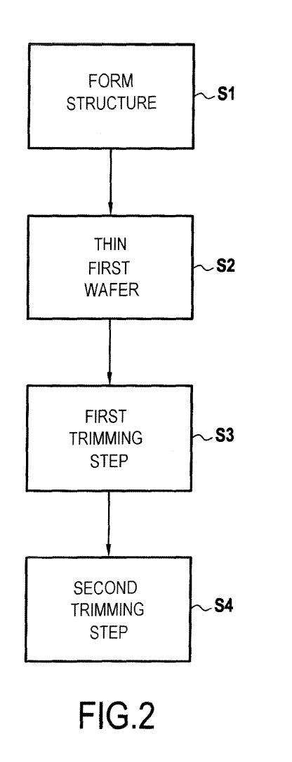

One implementation of a trimming method is described below with reference to FIGS. 1A to 1E and 2.

As can be seen in FIG. 1A, a structure 100 to be trimmed is formed by assembling a first wafer 101 with a second wafer 102, for example of silicon. The first and second wafers 101 and 102 shown here have the same diameter. They could, however, have different diameters. In the example described here, assembly is carried out by molecular bonding, a technique that is well known to the skilled person. It should be recalled that the principle of molecular bonding is based on bringing two surfaces into direct contact, i.e. without using a specific bonding material (adhesive, wax, solder etc). Such an operation requires that the surfaces to be bonded are sufficiently smooth, free from particles or contamination, and that they are brought sufficiently close together to allow contact to be initiated, typically to a distance of less than a few nanometers. Under such circumstances, forces of attraction between the two surfaces are high enough to cause molecular bonding (bonding induced by the set of attractive forces (van der Waals forces) due to electrons interacting between atoms or molecules of the two surfaces to be bonded together).

Adhesion between the two wafers is carried out at a low temperature so as not to damage the components and/or the first wafer. More precisely, after bringing the wafers into contact at ambient temperature, a bonding reinforcement anneal may be carried out, but at a temperature of less than 450° C., beyond which temperature certain metals such as aluminum or copper begin to creep.

An additional layer (not shown) of the oxide layer type may be formed on one of the two wafers before bringing them into contact. The first wafer 101 comprises a layer of components 103 and has a chamfered edge, i.e. an edge comprising an upper chamfer 104 and a lower chamfer 105. In FIG. 1A, the wafers have rounded chamfers. However, the wafers may also have chamfers or edge roundings with different shapes such as in the form of a bevel. In general, the term “chamfered edge” means any wafer edge at which the ridges have been bevelled so that contact between the two wafers close to their periphery is poor.

The wafers 101 and 102 are assembled one against the other by molecular bonding to form the structure 100 (step S1, FIG. 1B). Depending on the initial thickness of the first wafer 101, this may be thinned in order to form a transferred layer 106 with a predetermined thickness e (step S2, FIG. 1C), for example approximately 10 μm. The thickness e is measured between the upper face and the lower face of the layer or the wafer beyond the chamfered edge. This thinning step is preferably carried out before the trimming operation. Thinning of the first wafer, however, is still optional and trimming of the first wafer may be carried out without carrying out a prior thinning step.

Next, trimming of the structure 100 is carried out, consisting principally in eliminating an annular portion of the layer 106 comprising the chamfer 105, the chamfer 104 having been eliminated during thinning of the first wafer 101. In accordance with the invention, trimming commences with a first trimming step carried out by mechanical action or machining from the upper face of the layer 106 (edge grinding) (step S3, FIG. 1D). The mechanical action may be exerted by a grinder or any other tool that is suitable for mechanically wearing away the material of the layer. The width ld of the annular portion that is withdrawn corresponds to at least the width over which the chamfers extend. For wafers with a diameter of 100 mm, 200 mm, and 300 mm, the trimming width ld is generally in the range 2 mm to 8 mm, preferably in the range 2 mm to 5 mm.

During said first trimming step, the layer 106 is attacked over a depth Pd₁, which is less than the thickness e of the layer 106. More precisely, the depth Pd₁ is 50% or less of the thickness e. The transferred layers in general have a thickness in the range approximately 1 μm to 15 μm. The trimming depth during the first step may, for example, be of the order of 7 to 8 μm for a layer with a thickness of 15 μm.

This limitation to the depth of mechanical machining can reduce the heating and/or stresses both in the layer and at the bonding interface between the layer and the second wafer.

In FIG. 1D, the flank of the trimmed layer 106 is shown in a diagrammatic manner as being perpendicular to the plane of the substrate. However, depending on the type of grinder used, the profile of the trimming flank may have different shapes that are not entirely rectilinear, such as a slightly inwardly curved shape. In particular, such inwardly curved flanks are obtained when the grinder or trimming wheel is provided with grooves over at least one of these faces. It appears that the presence of such grooves encourages evacuation of the eliminated material and circulation of liquid (generally water) dispensed over and close to the wheel during the trimming operation. This further limits heating/stresses at the wafer edge and can further improve the trimming quality. When the trimmed flank of the layer or wafer does not have a near-rectilinear profile, the width of the first trimming step (such as width ld) corresponds at least to the width with which the wafer or layer is attacked (the trimming width can then be slightly reduced during trimming).

Trimming is then completed by a second trimming step that is at least partially non-mechanical, i.e. using material removal techniques other than those involving solely a mechanical wearing action or frictional action of a tool on the material of the layer (step S4, FIG. 1E). This second trimming step is carried out over the same width ld as during the first trimming step and over a depth Pd₂ corresponding at least to the remaining thickness of the layer 106 (i.e. e−Pd₁).

The second trimming step may in particular be carried out by chemical etching, also known as wet etching. The chemical etching solution is selected as a function of the material to be attacked. With silicon, for example, a tetramethylammonium hydroxide (TMAH) etching solution may be used.

The second trimming step may also be carried out using reactive ionic etching, also termed plasma etching or dry etching. This etching technique is well known to the skilled person. To recapitulate, it is a physico-chemical etching technique which employs both ionic bombardment and a chemical reaction between the ionized gas and the surface of the wafer or the layer to be etched. The atoms of gas react with the atoms of the layer or the wafer to form a new volatile species that is evacuated by a pumping device.

The second trimming step may also be carried out by chemical-mechanical polishing (CMP), a well known polishing technique which employs a fabric associated with a polishing solution containing both an agent (for example NH₄OH) that can chemically attack the surface of the layer and abrasive particles (for example silica particles) that can mechanically attack said surface. In contrast to dry and wet etching techniques that are entirely non-mechanical, chemical-mechanical polishing is only partially non-mechanical, but can limit the forces and heating on the wafer compared with entirely mechanical trimming such as grinding.

In accordance with yet another implementation, the second trimming step may be carried out by fracture or breakage of the remaining portion to be trimmed after the first trimming step. Fracture of this remaining portion may be carried out by exerting a pressure or a breaking force on the remaining portion, for example using a bearing tool, a jet of water, a laser, etc.

A particular but not exclusive field for the trimming method of the present invention is that of producing three-dimensional structures.

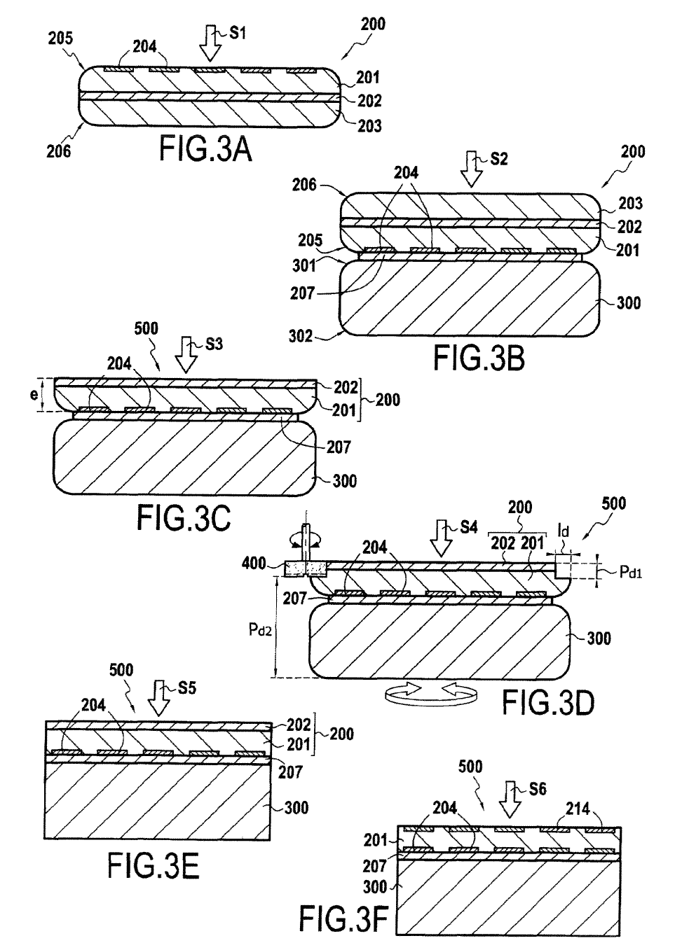

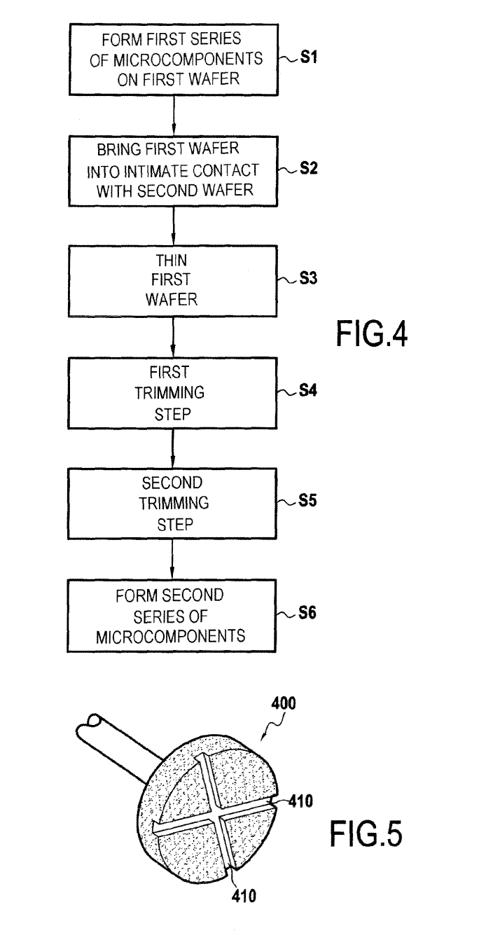

A method of producing a three-dimensional structure by transfer onto a support of a layer of microcomponents formed on an initial substrate in accordance with one implementation of the invention is described below in relation to FIGS. 3A to 3F and 4.

Producing the three-dimensional structure starts with the formation of a first series of microcomponents 204 on the surface of a first wafer 200 the edge of which has an upper chamfer 206 and a lower chamfer 205 (FIG. 3A, step S1). In the example described here, the first wafer 200 is a multilayer SOI type structure, i.e. it comprises a layer of silicon 201 disposed on a substrate 203, also of silicon, a buried oxide layer 202 (for example a layer of SiO₂) being present between the layer 201 and the substrate 203. The wafer 200 has a thickness in the range approximately 600 μm to 900 μm. For a wafer 200 mm in diameter (8 inches), the standard thickness is 725 μm.

The microcomponents 204 are formed by photolithography using a mask that can define zones for the formation of motifs corresponding to the microcomponents to be produced.

The face of the first wafer 200 comprising the microcomponents 204 is then brought into intimate contact with a face of a second wafer 300 (step S2, FIG. 3B) with a view to bonding by molecular bonding. The wafer 300 has a thickness of approximately 725 μm. In the same manner as the first wafer 200, the edge of the second wafer 300 has an upper chamfer 301 and a lower chamfer 302. A layer of oxide 207, for example formed from SiO₂, is also formed on the face of the first wafer 200 comprising the microcomponents 204. In the example described here, the first and second wafers 200, 300 have a diameter of 200 mm.

After bonding and as can be seen in FIG. 3C, the first wafer 200 is thinned to withdraw a portion thereof present above the layer of microcomponents 204 (step S3), here the substrate 203. At this stage of the method, the buried layer 202 is preferably retained in order to protect the components from possible contamination, particles, etc. The first wafer 200 may be thinned, in particular by a step of grinding or chemical-mechanical polishing (CMP) of the substrate 203, stopping 50 μm from the bonding interface, followed by a step of chemical attack up to the buried oxide layer 202, for example by etching with TMAH or KOH. Thinning may also be carried out by cleavage or fracture along a plane of weakness previously formed in the wafer 200 by atomic implantation. Advantageously, the buried insulating layer 202 is used to define the thickness of the remaining wafer 200. After the thinning step, the wafer 200 has a thickness e of approximately 10 μm. In other circumstances, its thickness may lie in the range 1 μm to 15 μm.

Thus, a composite structure 500 is obtained, formed by the second wafer 300 and the remaining portion of the first wafer 200.

In accordance with the invention, the first step of mechanical trimming of the structure 500 is carried out, consisting of eliminating an annular portion of the wafer 200 (step S4, FIG. 3D). This first trimming step is carried out using a grinder 400, the structure 500 being held in a rotating plate (not shown). As can be seen in FIG. 5, the grinder 400 has a lower face that is structured due to the presence of grooves 410. As indicated above, it has been observed that a grinder with such a structured face can limit heating and stresses. Clearly, trimming may also be carried out with grinders that do not have such structured faces.

During this first trimming step, the structure 200 is attacked over a width ld of approximately 4 mm and over a depth Pd₁ of approximately 5 μm, which in the example described here means that heating and/or stresses can be reduced sufficiently to prevent the appearance of macro peel-off and/or micro peel-off.

Trimming is then completed by the second non-mechanical trimming step carried out by chemical etching using, for example, a solution of TMAH. This second trimming step is carried out over a width ld and over a depth Pd₂ including the remaining thickness of the layer 201 as well as the thickness of the second layer 300 (step S5, FIG. 3E).

Once trimming of the structure 500 has been terminated, after having withdrawn the layer 202, a second layer of microcomponents 214 is formed at the exposed surface of the layer 201 (FIG. 3F, step S6). In the example described here, the microcomponents 214 are formed in alignment with the buried microcomponents 204. A photolithography mask is used for this purpose; it is similar to that used to form the microcomponents 204.

In a variation, the three-dimensional structure is formed by a stack of layers, i.e. by transfer of one or more additional layers onto the layer 201, each additional layer being in alignment with the directly adjacent layer or layers. The two-step trimming method of the invention is carried out for each transferred layer. Further, before each transfer of an additional layer, it is possible to deposit a layer of oxide on the exposed layer, for example a layer of tetraethoxysilane (TEOS) oxide, in order to facilitate assembly and protect the trimmed zones (for which the material of the subjacent wafer is exposed) from subsequent chemical attacks.

In accordance with a particular implementation, one of the layers of microcomponents may in particular comprise image sensors.

In accordance with another implementation, the components have already been formed in the second support wafer before assembly thereof with the first wafer constituting the transferred layer.

1-15. (canceled)

16. A method of trimming a structure while reducing applied mechanical friction, with the structure comprising a first wafer bonded to a second wafer, and with the first wafer having a chamfered edge and comprising electrical components, wherein the method comprises a first step of trimming the edge of the first wafer by mechanical machining over a predetermined depth of the first wafer followed by a second step of non-mechanical trimming over at least any remaining thickness of the first wafer, with the first trimming step being carried out with a grinder including grooves on its lower surface, wherein the reduced application of mechanical friction reduces heating and stresses such that macro and micro peel-off phenomena of the bonded wafers is limited compared to complete mechanical machining of the edge of the first wafer.

17. The method according to claim 16, wherein the first trimming step is carried out solely by mechanical wear of the material of the first wafer.

18. The method according to claim 16, wherein during the first trimming step, the first wafer is machined over a depth that is 50% or less of the thickness of the first wafer.

19. The method according to claim 16, wherein the first and second trimming steps are carried out over a width that is at least equal to the width over which the chamfered edge of the first wafer extends.

20. The method according to claim 19, wherein the first and second trimming steps are carried out over a width in the range of 2 mm to 8 mm for a wafer having a diameter of between 100 and 300 mm.

21. The method according to claim 16, wherein the second trimming step is carried out by chemical etching.

22. The method according to claim 16, wherein the second trimming step is carried out by plasma etching.

23. The method according to claim 16, wherein the second trimming step is carried out by chemical-mechanical polishing.

24. The method according to claim 16, wherein the second trimming step is carried out by fracture or breakage of the remaining portion to be trimmed after the first trimming step.

25. A method of producing a three-dimensional composite structure which comprises producing a layer of electrical components on one face of a first wafer, bonding the face of the first wafer that includes the layer of electrical components onto a second wafer, and trimming at least the first wafer in accordance with the method of claim 16.

26. The method according to claim 25, which further comprises, thinning the first wafer after bonding.

27. The method according to claim 25, which further comprises producing a second layer of electrical components on the face of the first wafer opposite to the face that includes the first layer of electrical components.

28. The method according to claim 25, which further comprises forming a layer of oxide on the face of the first wafer that includes the first layer of electrical components prior to bonding.

29. The method according to claim 25, wherein the first wafer has a SOI type structure.

30. The method according to claim 25, wherein at least the first layer of electrical components comprises image sensors.

31. In a method of trimming a chamfered edge of a structure by mechanical machining with the structure comprising a first wafer bonded to a second wafer, and the first wafer having the chamfered edge and comprising electrical components, the improvement which comprises conducting the mechanical machining of the chamfered edge of the first wafer over a predetermined depth of the first wafer with a grinder including grooves on its lower surface, and replacing part of the mechanical machining with non-mechanical trimming over at least any remaining thickness of the first wafer, wherein the trimming results in a reduced application of mechanical friction to reduce heating and stresses such that macro and micro peel-off phenomena of the bonded wafers is limited compared to complete mechanical machining of the chamfered edge of the first wafer.

32. The method according to claim 31, wherein the first wafer is mechanically machined over a depth that is 50% or less of the thickness of the first wafer and the non-mechanical machining is conducted to trim any remaining thickness of the first wafer.

33. The method according to claim 32, wherein the non-mechanical trimming is carried out by chemical etching, plasma etching, chemical-mechanical polishing or by fracture or breakage of the remaining thickness of the first wafer after the mechanical machining.
